(19) United States
(12) Patent Application Publication
(10) Pub. No.: US 2024/0223076 A1
(43) Pub. Date: Jul. 4, 2024

(54) GATE DRIVE CHARGE PUMP CIRCUIT FOR DYNAMIC BIAS CONTROL

(71) Applicant: TEXAS INSTRUMENTS INCORPORATED, Dallas, TX (US)

(72) Inventors: Bradford Lawrence HUNTER, Spicewood, TX (US); Jing YE, Dallas, TX (US)

(21) Appl. No.: 18/149,557

(22) Filed: Jan. 3, 2023

(51) Int. Cl. H02M 3/07; H02M 1/08

(52) U.S. Cl. CPC H02M 3/07; H02M 1/08

(57) ABSTRACT

In an example, a system includes a charge pump. The system includes a transistor coupled to a power terminal, the transistor gate coupled to a charge pump output. The system includes current sense circuitry having a power input, a load input and a sense output, where the power input is coupled to the power terminal, the current sense circuitry is configured to provide a sense signal at the sense output, and the sense signal represents a polarity and a magnitude of a current at the load input. The system includes a controller having a sense input coupled to the sense output and a control output coupled to the control input, where the controller is configured to provide a control signal at the control output responsive to the sense signal, and the charge pump is configured to adjust a voltage at the charge pump output responsive to the control signal.

### BACKGROUND

Batteries may supply power to electronic circuits in a variety of applications. Battery packs may include multiple batteries and a battery management system to control the charging, discharging, and monitoring of the batteries. Batteries may be monitored for performance and safety, such as by monitoring voltage, current, temperature, cooling, history, health of the battery cells, state of balance of the battery cells, etc.

### SUMMARY

In accordance with at least one example of the description, a system includes a charge pump having a control input and a charge pump output. The system includes a transistor coupled in series with a power terminal, the transistor having a gate coupled to the charge pump output. The system also includes current sense circuitry having a power input, a load input and a sense output, in which the power input is coupled to the power terminal, the current sense circuitry is configured to provide a sense signal at the sense output, and the sense signal represents a polarity and a magnitude of a current at the load input. The system includes a controller having a sense input and a control output, in which the sense input is coupled to the sense output, the control output is coupled to the control input, and the controller is configured to provide a control signal at the control output responsive to the sense signal, and the charge pump is configured to adjust a voltage at the charge pump output responsive to the control signal.

In accordance with at least one example of the description, a method includes measuring, by a control circuit, a load current of a transistor coupled to a power source, where a gate of the transistor is coupled to a charge pump. The method also includes, responsive to a negative polarity load current and the load current being below a threshold, reducing, by the control circuit, an output voltage of the charge pump. The method includes, responsive to a negative polarity load current and the load current being above a threshold, increasing, by the control circuit, the output voltage of the charge pump. The method includes, responsive to a positive polarity load current, increasing, by the control circuit, the output voltage of the charge pump.

In accordance with at least one example of the description, a system includes a first charge pump having a first charge pump output coupled to a gate of a first n-channel transistor. The system also includes a second charge pump having a second charge pump output coupled to a gate of a second n-channel transistor, the second n-channel transistor coupled in series to the first n-channel transistor. The system includes a power source coupled to the first n-channel transistor and the second n-channel transistor. The system also includes current sense circuitry configured to provide a sense signal representing a polarity and a magnitude of a current through the first n-channel transistor and the second n-channel transistor. The system includes a controller configured to provide a control signal responsive to the sense signal, where the control signal is provided to the first charge pump and the second charge pump, and where the first charge pump and the second charge pump are configured to adjust a voltage at the first charge pump output and the second charge pump output, respectively, responsive to the control signal.

### BRIEF DESCRIPTION OF THE DRAWINGS

FIG. 1 is a block diagram of a system for dynamic control of a gate drive charge pump circuit in accordance with various examples.

FIG. 2 shows graphs of example transistor on-state resistance and gate leakage in accordance with various examples.

FIG. 3 is a graph of charge pump output voltage versus time in accordance with various examples.

FIG. 4 is a block diagram of a system for dynamic control of a gate drive charge pump circuit in accordance with various examples.

FIG. 5 is a flow diagram of a method for dynamic control of a gate drive charge pump circuit in accordance with various examples.

FIG. 6 is a flow diagram of a method for dynamic control of a gate drive charge pump circuit in accordance with various examples.

The same reference numbers or other reference designators are used in the drawings to designate the same or similar (functionally and/or structurally) features.

### DETAILED DESCRIPTION

A battery pack may include one or more batteries and electronics to monitor and control the batteries. The electronics to monitor and control the batteries may be embodied in one or more integrated circuits (IC) within a chip. The chip may drive two high-side external transistors, which may be N-channel field effect transistors (NFETs) in an example. One NFET charges the battery, and the other NFET discharges the battery. A protector IC may indirectly monitor the current carried by the NFETs using a series sense resistor. The series sense resistor monitors the current, and if the charging current or charging voltage is too high, the charge NFET is turned off. If the discharge current is too high (such as with a short circuit), the discharge NFET is turned off. If the battery is significantly discharged and the battery voltage is low, the discharge NFET is turned off.

Charge pump circuits may provide voltages higher than the power supply voltage to turn on the NFETs. For each NFET, a voltage sensing regulation system monitors the gate to source voltage (Vas) of the NFET to regulate the charge pump output voltage to a particular level. The V_{GS} may be regulated by turning on and off a clock source for the charge pump. If V_{GS} reaches the appropriate level, the clock source is turned off to turn off the charge pump temporarily. As the charge pump loses charge (via gate to source leakage of the NFETs, a V_{GS} safety resistor, leakage in the IC, etc.), the charge pump is turned back on. This type of regulation is called hysteretic control or skip mode control.

If the device using the battery pack is in use, the NFETs may operate more efficiently with a higher charge pump voltage. The efficiency is increased due to a reduced drain-to-source resistance of the NFETs as the charge pump voltage is increased. However, if the device is not in use, an increased charge pump voltage causes increased gate leakage current of the NFETs. In examples herein, multiple modes of operation for the charge pump are implemented. The current through the NFETs or through a sense resistor is measured, and the charge pumps are placed in different modes responsive to the current measurement. If the battery pack is charging, the charge pump voltage is set to a high voltage. If the battery pack is discharging and the current is high, the device is in operation, and the charge pump voltage is set to a high voltage to increase the efficiency of the NFETs. If the battery pack is discharging and the current is low, the device is in a standby or idle state, and the charge pump voltage is decreased to reduce the leakage currents. In other examples, more than two charge pump voltage levels may be implemented and selected from based on the current measurement.

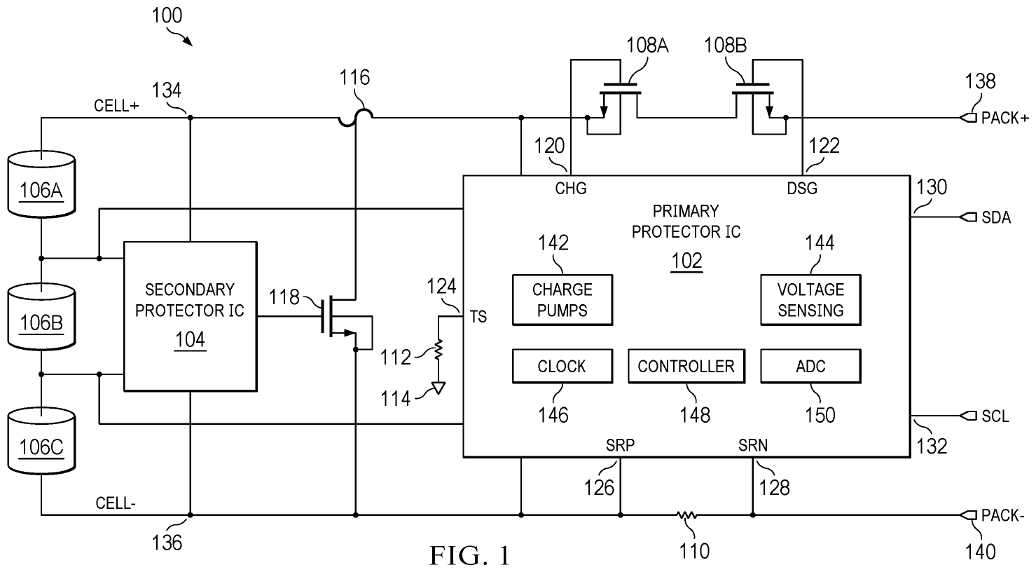

FIG. 1 is a block diagram of a system 100 for dynamic control of a gate drive charge pump circuit in accordance with various examples herein. System 100 includes a primary protector IC 102, secondary protector IC 104, battery cells 106A, 106B, 106C (collectively, battery cells 106), and NFETs 108A and 108B (collectively, NFETs 108). System 100 also includes sense resistor 110, resistor 112, ground (or common node) 114, fuse 116, and transistor 118. Primary protector IC 102 includes a charge pin 120 (CHG), a discharge pin 122 (DSG), a temperature sensor (TS) pin 124, a sense resistor positive (SRP) pin 126, a sense resistor negative (SRN) pin 128, a serial data (SDA) pin 130, and a serial clock (SCL) pin 132. System 100 includes a node 134 where battery cells 106 provide a CELL+ voltage, and a node 136 where battery cells 106 provide a CELL− voltage. System 100 also includes a PACK+ pin 138 and a PACK− pin 140.

Primary protector IC 102 also includes charge pumps 142, voltage sensing circuit 144, clock 146, controller 148, and analog to digital converter (ADC) 150. Primary protector IC 102 drives NFETs 108A and 108B, which are high-side external FETs in this example. In other examples, the NFETs 108 may be internal to an IC. NFET 108A is a charge FET, and NFET 108B is a discharge FET in this example. NFET 108A charges the battery cells 106, and NFET 108B controls the discharging current of the battery cells 106. Primary protector IC 102 controls the NFETs 108 via signals from charge pin 120 and discharge pin 122.

Primary protector IC 102 also monitors the voltage and/or current through NFETs 108 with sense resistor 110 in one example. Primary protector IC 102 uses SRP pin 126 and SRN pin 128 to monitor the current. If the current is above a threshold, the voltage is too high across the NFETs 108 and the charge NFET 108A is turned off by primary protector IC 102 via a signal from charge pin 120. If primary protector IC 102 detects too much discharge current (such as a short circuit situation), the discharge NFET 108B is turned off via a signal from discharge pin 122. Also, if the battery is discharged substantially and the voltage is below a threshold, the discharge NFET 108B is turned off.

TS pin 124 may be a thermistor that monitors the temperature of battery cells 106 in one example. If the battery cells 106 are too hot, charge NFET 108A may be turned off to protect the battery cells 106. Alternatively, discharge NFET 108B may be turned off to prevent the hot battery from operating. Secondary protector IC 104 monitors battery cells 106 for an overcharge, and manages fuse 116. Primary protector IC 102 may turn off NFETs 108 responsive to the battery voltage. If an NFET 108 is damaged, primary protector IC 102 may not be able to prevent overcharging. Fuse 116 provides backup protection. The voltage threshold monitored by primary protector IC 102 may be lower than the voltage threshold monitored by secondary protector IC 104. If primary protector IC 102 is unable to reduce the voltage by turning off NFETs 108, secondary protector IC 104 may blow fuse 116. In some examples, blowing fuse 116 permanently disables system 100.

In examples herein, primary protector IC 102 includes two charge pumps 142 that independently drive each of the NFETs 108. For both NFETs 108, voltage sensing circuit 144 monitors the gate to source voltage V_{GS} on each NFET 108 to regulate the output voltage of each of the charge pumps 142. V_{GS} may be regulated by turning on and off clock 146, which is a clock source for the charge pumps 142. If V_{GS} reaches a predetermined level, clock 146 may be turned off to turn off a charge pump 142 temporarily. As a charge pump 142 loses charge, (via gate to source leakage of NFET 108, a V_{GS} safety resistor, leakage in the IC, etc.) the charge pump 142 may be turned on by turning clock 146 back on. ADC 150 performs current sensing to determine which state to place charge pumps 142 in. Controller 148 activates charge pumps 142 and clock 146 responsive to the current sensing signals from ADC 150.

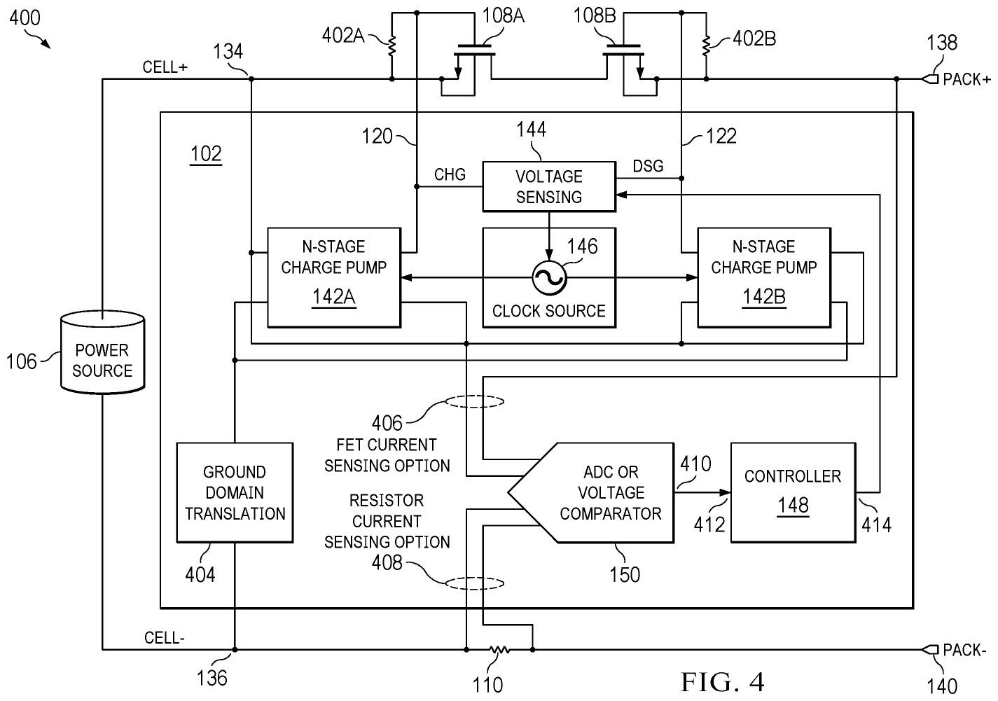

As described herein, system 100 dynamically adjusts the gate drive of NFETs 108 responsive to current sense monitoring performed by primary protector IC 102. Multiple modes of operation for the charge pumps 142 are implemented, as described above. If the battery cells 106 are charging, the charge pump 142 voltage is set to a high voltage. If the battery cells 106 are discharging and the current is high, system 100 is in operation and the charge pump 142 voltage is set to a high voltage to increase the efficiency of NFETs 108. If the battery cells 106 are discharging and the current is low, system 100 is in a standby or idle state and the charge pump 142 voltage is decreased to reduce the leakage currents. Additional description of the operation of the circuitry within system 100 is provided with respect to FIG. 4 below.

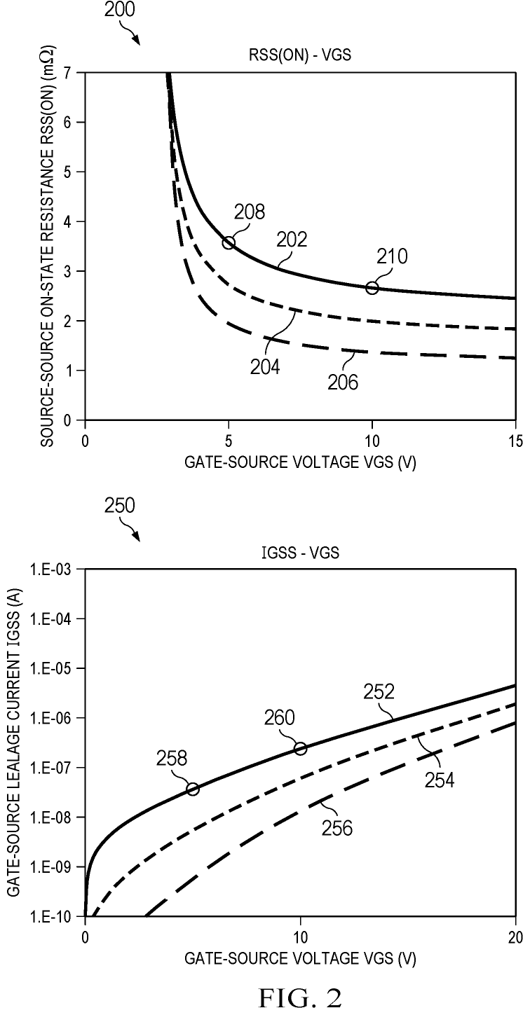

FIG. 2 includes graphs of example NFET on-state resistance and gate leakage in accordance with various examples herein. Graphs 200 and 250 may be graphs for NFETs 108 in one example. Other FETs may be useful in other examples, and may have on-state resistance and/or gate leakage that differs from graphs 200 and 250.

In one example, graph 200 is a graph of source-to-source on-state resistance (in mΩ) for NFETs 108 on the y-axis, and gate-to-source voltage V_{GS} (in volts (V)) on the x-axis. The NFETs 108 may be produced and sold as a package, so source-to-source on-state resistance is shown in graph 200. Graph 200 includes waveforms 202, 204, and 206. Waveform 202 shows the on-state resistance vs. V_{GS} at a temperature of 85° C. Waveform 204 shows the on-state resistance vs. Vas at a temperature of 25° C. Waveform 206 shows the on-state resistance vs. V_{GS} at a temperature of −40° C. Graph 200 shows that as V_{GS} increases on the x-axis, the on-state resistance decreases. This indicates that the NFETs 108 become more efficient as V_{GS} increases. However, this may come at a cost of the charge pumps being on more often and increasing leakage current, as described below.

Two locations are marked on waveform 202 as an example. Location 208 indicates that at 85° C. and a V_{GS} of 5 V, on-state resistance is approximately 3.5 mΩ. Location 210 indicates that at 85° C. and a V_{GS} of 10 V, on-state resistance is approximately 2.7 mΩ. As described above, resistance decreases as the V_{GS} increases.

Graph 250 is a graph of gate-to-source leakage current in amps (A) on the x-axis, and V_{GS} (in V) on the y-axis. Graph 250 includes waveforms 252, 254, and 256. Waveform 252 shows the leakage current vs. V_{GS} at a temperature of 85° C. Waveform 254 shows the leakage current vs. V_{GS} at a temperature of 25° C. Waveform 256 shows the leakage current vs. V_{GS} at a temperature of −40° C. Graph 250 shows that as V_{GS} increases on the x-axis, the leakage current also increases.

Two locations are marked on waveform 252 as an example. Location 258 indicates that at 85° C. and a V_{GS} of 5 V, leakage current is approximately 30 nanoamps (nA). Location 260 indicates that at 85° C. and a V_{GS} of 10 V, leakage current is approximately 150 nA. In this example, a change in V_{GS} from 5 V to 10 V could have a 5× impact on the size of the leakage current. The gate leakage current shown in graph 250 may be one of the largest current consumption contributors of system 100. Increasing the V_{GS} therefore has advantages (less on-state resistance) and disadvantages (higher leakage current).

In examples herein, multiple modes of operation for charge pumps 142 are implemented, as described above. In one example, if both charge pumps 142 are on, system 100 may consume 100 microamps at a V_{GS} of 10 V. At a V_{GS} of 5 V, the current may be reduced to 20 microamps. If system 100 is discharging a lot of current (e.g., a load is being actively driven by system 100, such as powering a device), battery cells 106 may only produce 15 to 30 minutes of run time. One example device with this type of run time may be a power tool such as an electric trimmer. During run time, the leakage current of the charge pumps 142 (e.g., graph 250) is mostly irrelevant to the operation of the device. Instead, the maximum efficiency of the device is more relevant (graph 200), and a higher V_{GS} provides more efficiency. Alternatively, if the device is not in use (such as a device that may go days or weeks without use), the leakage current becomes more important, as a high leakage current may drain the battery cells 106 as the device sits unused. Therefore, the device has two different use cases. When system 100 is driving a load (e.g., the device is in use), high efficiency is important, which is achieved with a higher Vas. When the device is idle, lower leakage currents are important to preserve the charge in the battery cells 106. As described herein, the current through the NFETs 108 or through a sense resistor 110 is measured, and the charge pumps 142 are placed in different modes (e.g., a V_{GS} of 5 V or 10 V) responsive to the current measurement.

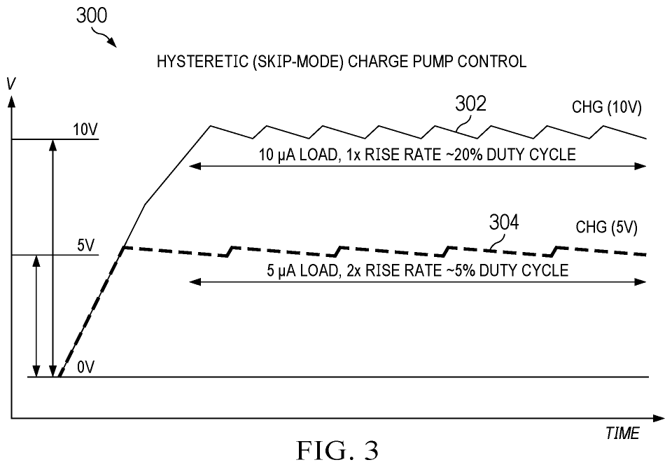

FIG. 3 is a graph 300 of charge pump output voltage versus time in accordance with various examples herein. Graph 300 shows hysteretic control or skip mode control of the charge pumps 142 as described above. The x-axis is the output voltage of the charge pump 142 in V, and the y-axis is time.

Graph 300 includes two waveforms 302 and 304. Waveform 302 represents a charge pump 142 output voltage of 10 V, with a 10 microamp load, and a 1× rise rate for the output voltage. In this example, the charge pump 142 has an approximately 20% duty cycle. As shown in waveform 302, the charge pump 142 is turned on as needed to create the series of rising edges, and then the voltage slowly decreases over time before the next rising edge. This creates a slight ripple in the waveform 302. The ripple does not affect the output of battery cells 106 or system 100.

Waveform 304 represents a charge pump 142 output voltage of 5 V, with a 5 microamp load and a 2× rise rate. In this example, waveform 304 has an approximately 5% duty cycle. As with waveform 302, the charge pump 142 is turned on as needed to create the series of rising edges, and then the voltage slowly decreases over time before the next rising edge.

In the example of waveform 302, the charge pump 142 is turned on more frequently than in the example of waveform 304. The duty cycle of 20% for waveform 302 is higher than the duty cycle of 5% for waveform 304. Therefore, more power is saved in the waveform 304 example compared to the waveform 302 example. That is, more power is saved if the charge pump 142 output voltage is 5 V compared to 10 V. As described above, if the system 100 is idle, the charge pump 142 output voltage may be reduced (e.g., from 10 V to 5 V) to reduce power consumption. Graph 300 shows one example of how the reduction in power consumption is achieved.

FIG. 4 is a block diagram of a system 400 for dynamic control of a gate drive charge pump circuit in accordance with various examples herein. System 400 includes many of the components described above with respect to system 100 in FIG. 1, and like numerals indicate like components. System 400 includes primary protector IC 102, battery cells 106 (shown as one battery in this example), NFETs 108A and 108B, and sense resistor 110. Secondary protector IC 104 is not shown in FIG. for simplicity. System 400 includes node 134, node 136, PACK+ pin 138, and PACK− pin 140. System 400 also includes V_{GS} safety resistors 402A and 402B (collectively, V_{GS} safety resistors 402). V_{GS} safety resistors 402 are optional and may be absent in other examples.

Primary protector IC 102 includes charge pin 120, discharge pin 122, charge pumps 142A and 142B, voltage sensing circuit 144, clock 146, controller 148, and ADC 150. ADC 150 may be replaced with a voltage comparator in some examples. Primary protector IC 102 also includes ground domain translation 404, which may be absent in other examples. Ground domain translation 404 provides an internal ground or common potential rail for internal components of primary protector IC 102, such as charge pumps 142. Primary protector IC 102 shows two current sensing options: FET current sensing option 406 and resistor current sensing option 408. In examples herein, either current sensing option may be useful. In some examples, only one of the current sensing options 406 or 408 may be present. If resistor current sensing option 408 is absent in some examples, sense resistor 110 may be absent as well.

Each current sensing option 406 or 408 includes any suitable current sense circuitry that has a power input and a load input. The power input and the load input may be provided to ADC 150, which has a sense output 410. A sense signal is provided at the sense output 410 that represents a polarity and a magnitude of a current at the load input. The sense signal is provided to controller 148 at a sense input 412. Controller 148 has a control output 414, and controller 148 is configured to provide a control signal at the control output 414 responsive to the sense signal. As described below, the charge pump 142 is configured to adjust a voltage at the charge pump 142 output responsive to the control signal. In other examples, a control circuit or control circuitry may be useful for performing the functions of controller 148 as described herein.

In system 400, NFETs 108 represent a high-side FET. Charge pumps 142 provide gate voltages to NFETs 108. To turn on NFET 108A or 108B, the NFET 108 needs a gate voltage higher than its source voltage. For each NFET 108, a voltage sensing regulation system monitors V_{GS} to regulate the output voltages of the charge pumps 142 to a particular level. The V_{GS} of each NFET 108 may be regulated by turning off clock 146, which turns off the charge pumps 142 temporarily. Responsive to V_{GS} reaching the appropriate level, clock 146 is turned back on. If charge pumps 142 subsequently lose charge (via gate to source leakage of NFETS 108, V_{GS} safety resistors 402, leakage in primary protector IC 102, etc.), charge pumps 142 are turned back on. Each charge pump 142 has a charge pump output that is coupled to an NFET 108. As an example, charge pump 142A has a charge pump output (e.g., a first charge pump output) coupled to a gate of NFET 108A via charge pin 120. Charge pump 142B has a charge pump output (e.g., a second charge pump output) coupled to a gate of NFET 108B via discharge pin 122. NFETs 108 are each coupled between a charge pump 142 output and a power terminal. In one example, one power terminal may be node 134, while the other power terminal may be PACK+ 138.

In an example, ADC 150 determines the operation mode of the charge pumps 142 responsive to the current sensing. ADC 150 may be a low power ADC that operates periodically by turning on to check the current, and then turning off. In one example, ADC 150 uses the sense resistor 110 to measure the current (e.g., resistor current sensing option 408), which is indicative of the current through NFETs 108. A high-tolerance sense resistor 110 may take up board space and increase cost in some examples. Therefore, in other examples, FET current sensing option 406 is useful. FET current sensing option 406 senses current by monitoring the voltage across NFETs 108. However, the resistance of NFETs 108 may be dependent on temperature and process, and therefore may not be as accurate as resistor current sensing option 408 in some examples. In other examples, primary protector IC 102 may determine current by monitoring CELL+ and PACK+ voltages (not shown in FIG. 4). Any suitable method for monitoring or measuring current may be useful for examples herein.

ADC 150 produces an output signal based on input voltages provided to ADC 150 and the selected current sensing option. The output signal is a digital signal provided to controller 148 in one example, and controller 148 determines a size and polarity of the sense current based on the output signal from ADC 150. The sense current is indicative of the current through NFETs 108. Controller 148 may compare the output signal from ADC 150 to a one or more thresholds using any suitable software, hardware, algorithm, digital logic, or state machine in an example. Based on the comparison to the one or more thresholds, controller 148 provides a signal to voltage sensing circuit 144. Responsive to the signal, voltage sensing circuit 144 sets the output voltage levels of charge pumps 142. Voltage sensing circuit 144 may set the charge pump output voltage levels by turning on and off clock 146 with an appropriate duty cycle as described above. In one example, voltage sensing circuit 144 compares the charge NFET (e.g., NFET 108A) or discharge NFET (e.g., NFET 108B) gate-to-source voltage level to a reference voltage via an internal comparator, and determines if the charge pump output voltage is above or below a threshold. If it is above a threshold, voltage sensing circuit 144 turns off clock 146. If the charge pump output voltage is below a threshold, voltage sensing circuit 144 turns on clock 146 to activate the charge pumps 142. Clock 146 provides signals to a control input of each charge pump 142. Voltage sensing circuit 144 may include any suitable controller, hardware, circuitry, or digital logic to perform the functions described herein.

As described herein, the current through the NFETs 108 or through sense resistor 110 is measured, and charge pumps 142 are placed in different modes responsive to the current measurement. If the battery cell 106 is charging, charge pump 142 voltage is set to a high voltage. If battery cell 106 is discharging and the current is high (e.g., above a predetermined threshold), the device is in operation and the charge pump 142 voltage is set to a high voltage to increase the efficiency of the NFETs 108 (such as 10 V). If the battery cell 106 is discharging and the current is low (e.g., below a predetermined threshold), the device is in a standby or idle state and the charge pump 142 voltage is decreased to reduce the leakage currents of NFETs 108 (e.g., charge pump 142 voltage set to 5 V). In other examples, more than two charge pump 142 voltage levels may be implemented, and selected from based on the current sensing.

In some examples, one of the NFETs 108 may be optional and absent, with only one NFET 108 in system 400. In other examples, a discharge NFET 108 (such as NFET 108B) may be a high-side FET, and a charge NFET 108 (such as NFET 108A) may be a low-side FET. Some examples herein may include a single NFET 108 and a single charge pump 142. In examples herein, the charge pumps 142 be any suitable charge pump and may include any suitable circuitry. Clock 146 may be any appropriate clock circuitry or have any suitable topology. Also, any current sensing method is useful, having any suitable circuitry.

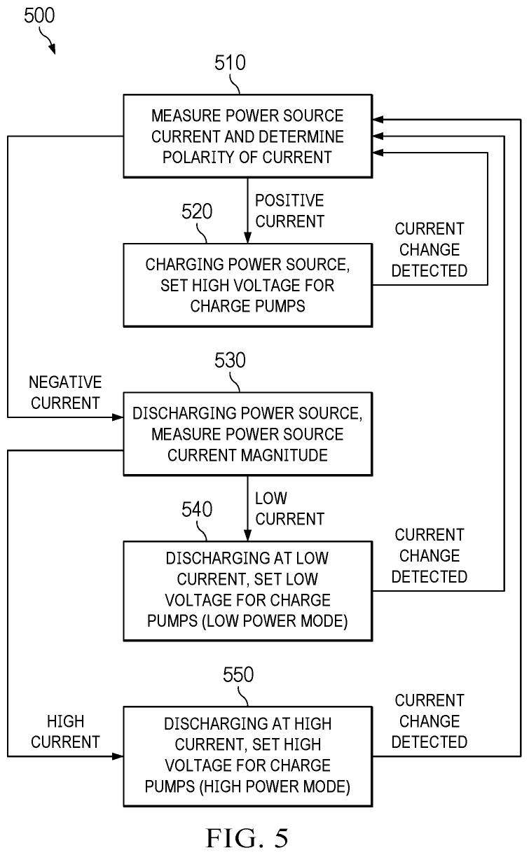

FIG. 5 is a flow diagram of a method 500 for dynamic control of a gate drive charge pump circuit in accordance with various examples herein. The steps of method 500 may be performed in any suitable order. The hardware components described above with respect to FIGS. 1 and 4 may perform method 500 in some examples. Any suitable hardware, software, or digital logic may perform method 500 in some examples.

Method 500 indicates how primary protector IC 102 determines which state to place charge pumps 142 in. Method 500 begins at 510, where the ADC 150 and controller 148 measures the power source current and determines the polarity of the current (e.g., positive or negative). Any suitable current sensing may be useful in examples herein. If a positive current is detected, method 500 proceeds to 520. A positive current indicates that the battery cells 106 are charging. Saving power is not a concern if battery cells 106 are charging, so the magnitude of the current does not need to be determined if a positive current is detected in 510.

At 520, the positive current has been detected as described above. The battery cells 106 are charging, so charge pumps 142 may be set to a high (or the highest) voltage level, and then method 500 returns to 510 to monitor the state of the current. The current may alternatively be monitored at 520, and if a current change is detected (e.g., the polarity of the current changes), method 500 may return to 510.

If a negative current is detected at 510, method 500 proceeds to 530. A negative current indicates that battery cells 106 are discharging. If battery cells 106 are discharging, the magnitude of the current is measured to determine the state of the device or system. In this example, the magnitude of the current is determined to be either high (above a threshold) or low (below a threshold), and therefore the charge pumps 142 have two different operating voltages. However, in other examples, any number of operating states for the charge pumps 142 may be implemented. ADC 150 and controller 148 may quantize the current measurement into any number of levels, and then implement different output voltage values of the charge pump 142 for each level. In many examples, two output voltage levels for charge pump 142 are suitable for providing efficient operation, but different numbers of output voltage levels may be useful in other examples. In some examples, the output voltage of charge pumps 142 could change linearly with the current measurement.

At 530, the magnitude of the current is measured to determine whether the current is above a threshold or below a threshold. If the current is low (below the threshold), method 500 proceeds to 540. If the current is high (above the threshold), method 500 proceeds to 550.

At 540, the current is below the threshold. This state indicates that the current is discharging, but the current is low. If the current is low, the device is likely in an idle or standby state, and the battery cells 106 are not actively driving a load. The output voltage of the charge pumps 142 is set to a low voltage (e.g., 5 V). This may be referred to as a low power mode. The low voltage reduces leakage current as shown in graph 250. After placing the charge pumps 142 in the low power mode, method 500 may return to 510 to continue monitoring the current to determine the polarity and magnitude of the current. The current may be periodically re-tested by ADC 150 and controller 148 to determine whether a mode change is needed.

If the current is high in step 530, method 500 proceeds to 550. At 550, a high current is discharging, which indicates that battery cells 106 are actively driving a load. The system or device is therefore in use or in an active state. If the device is in use, the output voltage of the charge pumps 142 is set to a high voltage (e.g., 10 V). This may be referred to as a high power mode. The high voltage provides efficient operation of the NFETs 108 as shown in graph 200. After placing the charge pumps 142 in the high power mode, method 500 may return to 510 to continue monitoring the current to determine the polarity and magnitude of the current. The current may be periodically re-tested by ADC 150 and controller 148 to determine whether another mode change is needed. Therefore, method 500 provides one example of dynamic control of a gate drive charge pump circuit for more efficient operation.

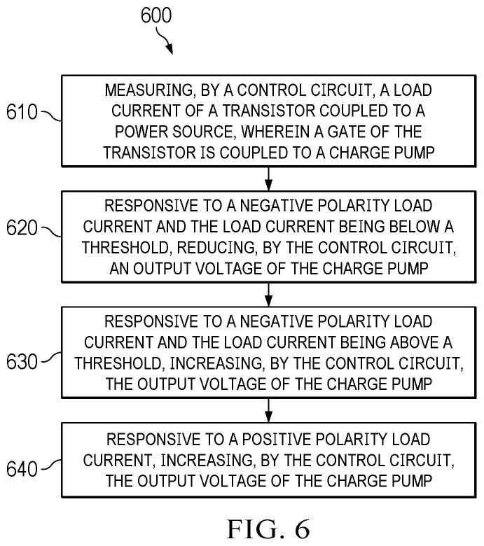

FIG. 6 is a flow diagram of a method 600 for dynamic control of a gate drive charge pump circuit in accordance with various examples herein. The steps of method 600 may be performed in any suitable order. The hardware components described above with respect to FIGS. 1 and 4 may perform method 600 in some examples. Any suitable hardware, software, or digital logic may perform method 600 in some examples.

Method 600 begins at 610, where a controller or control circuit measures a load current of a transistor coupled to a power source, where a gate of the transistor is coupled to a charge pump. As described above, the load current may be measured using any suitable sensing circuitry. The sense signal may be provided to a controller, and the controller may act responsive to the sense signal.

Method 600 continues at 620, where responsive to a negative polarity load current and the load current being below a threshold, the charge pump reduces an output voltage. A controller or control circuit may send a control signal to additional circuitry that reduces the output voltage of the charge pump. In one example, a clock such as clock 146 may be turned off to reduce the output voltage of the charge pump. In other examples, any suitable technique may be useful for reducing the output voltage of the charge pump. A negative polarity load current and the current being below a threshold indicates that the system is discharging current, but is likely not actively driving a load. Therefore, the system may be in an idle state.

Method 600 continues at 630, where responsive to a negative polarity load current and the load current being above a threshold, the charge pump increases the output voltage. A controller or control circuit may send a control signal to additional circuitry that increases the output voltage of the charge pump. In one example, the output voltage may be increased by turning on a clock such as clock 146. Other techniques to increase the output voltage of the charge pump may be useful in other examples. A negative polarity load current and the current being above a threshold indicates that the system is discharging current at a high rate and is likely actively driving a load. As described above, in this state or mode of operation the efficiency of the NFETs 108 is more important than the leakage currents, so the charge pump output voltage may be increased to reduce the on-resistance of the NFETs 108.

Method 600 continues at 640, where responsive to a positive polarity load current, the charge pump increases the output voltage. A controller or control circuit may send a control signal to additional circuitry that increases the output voltage of the charge pump. In one example, the output voltage may be increased by turning on a clock such as clock 146. Other techniques to increase the output voltage of the charge pump may be useful in other examples. A positive polarity load current indicates that the battery is charging. As described above, in this state or mode of operation the efficiency of the NFETs 108 is more important than the leakage currents, so the charge pump output voltage may be increased to reduce the on-resistance of the NFETs 108 while the battery is charging.

In examples herein, multiple modes of operation for one or more gate drive charge pumps are implemented. A current through the high-side NFETs or through a sense resistor in a power source application is measured, and the charge pumps are placed in different modes responsive to the current measurement. If the battery pack is charging, the charge pump output voltage is set to a high voltage. If the battery pack is discharging and the current is high, the device is in operation and the charge pump output voltage is set to a high voltage to increase the efficiency of the NFETs. If the battery pack is discharging and the current is low, the device is in a standby or idle state and the charge pump output voltage is decreased to reduce the leakage currents. In other examples, more than two charge pump output voltage levels may be implemented, and selected from based on the current measurement.

As described herein, the charge pump output voltages are dynamically adjusted based upon the system load current polarity and magnitude. The on-resistance of the NFETs may be reduced at high load currents with an increased gate-to-source voltage when efficiency is important. In a low-power mode of operation, the on-resistance may be increased by decreasing the gate-to-source voltage and reducing the current consumption of the charge pumps. The examples herein may provide extended battery or power source life by reducing current consumption of the charge pumps that control the operation of the NFETs.

In this description, the term “couple” may cover connections, communications or signal paths that enable a functional relationship consistent with this description. For example, if device A provides a signal to control device B to perform an action, then: (a) in a first example, device A is directly connected to device B; or (b) in a second example, device A is coupled to device B through intervening component C if intervening component C does not alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A system, comprising:
a charge pump having a control input and a charge pump output;
a transistor coupled in series with a power terminal, the transistor having a gate coupled to the charge pump output;
current sense circuitry having a power input, a load input and a sense output, in which the power input is coupled to the power terminal, the current sense circuitry is configured to provide a sense signal at the sense output, and the sense signal represents a polarity and a magnitude of a current at the load input; and
a controller having a sense input and a control output, in which the sense input is coupled to the sense output, the control output is coupled to the control input, and the controller is configured to provide a control signal at the control output responsive to the sense signal, and the charge pump is configured to adjust a voltage at the charge pump output responsive to the control signal.

2. The system of claim 1, wherein the transistor is an n-channel field-effect transistor (NFET).

3. The system of claim 1, wherein the transistor is a first transistor, and the first transistor is coupled in series to a second transistor.

4. The system of claim 3, wherein the first transistor is configured to discharge a power source, and the second transistor is configured to charge the power source.

5. The system of claim 1, wherein the charge pump is configured to increase the voltage at the charge pump output responsive to a positive polarity of the current.

6. The system of claim 1, wherein the charge pump is configured to decrease the voltage at the charge pump output responsive to a negative polarity of the current and the magnitude of the current being below a predetermined threshold.

7. The system of claim 1, wherein the charge pump is configured to increase the voltage at the charge pump output responsive to a negative polarity of the current and the magnitude of the current being above a predetermined threshold.

8. The system of claim 1, wherein the current sense circuitry includes a current sense resistor coupled to the power terminal.

9. The system of claim 1, wherein the sense output is an output of an analog-to-digital converter.

10. The system of claim 1, wherein the current sense circuitry is coupled to the transistor.

11. The system of claim 1, wherein the control input is configured to receive a signal from a clock.

12. The system of claim 1, wherein the charge pump is a first charge pump, the charge pump output is a first charge pump output, the transistor is a first transistor, and the system further comprises:
a second charge pump having a second charge pump output; and
a second transistor coupled to the second charge pump output, wherein the second transistor is coupled in series to the first transistor.

13. A method, comprising:
measuring, by a control circuit, a load current of a transistor coupled to a power source, wherein a gate of the transistor is coupled to a charge pump;
responsive to a negative polarity load current and the load current being below a threshold, reducing, by the control circuit, an output voltage of the charge pump;
responsive to a negative polarity load current and the load current being above a threshold, increasing, by the control circuit, the output voltage of the charge pump; and
responsive to a positive polarity load current, increasing, by the control circuit, the output voltage of the charge pump.

14. The method of claim 13, wherein the transistor is a first transistor, and the first transistor is coupled in series to a second transistor.

15. The method of claim 13, wherein measuring the load current includes measuring the load current through a sense resistor.

16. The method of claim 13, wherein increasing the output voltage of the charge pump increases a gate-to-source voltage of the transistor.

17. The method of claim 13, wherein decreasing the output voltage of the charge pump decreases a gate-to-source voltage of the transistor.

18. A system, comprising:
a first charge pump having a first charge pump output coupled to a gate of a first n-channel transistor;
a second charge pump having a second charge pump output coupled to a gate of a second n-channel transistor, the second n-channel transistor coupled in series to the first n-channel transistor;
a power source coupled to the first n-channel transistor and the second n-channel transistor;
current sense circuitry configured to provide a sense signal representing a polarity and a magnitude of a current through the first n-channel transistor and the second n-channel transistor; and
a controller configured to provide a control signal responsive to the sense signal, wherein the control signal is provided to the first charge pump and the second charge pump, and wherein the first charge pump and the second charge pump are configured to adjust a voltage at the first charge pump output and the second charge pump output, respectively, responsive to the control signal.

19. The system of claim 18, wherein the sense signal is provided by a current sense resistor.

20. The system of claim 18, wherein the first n-channel transistor is configured to charge the power source, and the second n-channel transistor is configured to discharge the power source.
